(19) United States
(12) Patent Application Publication
(10) Pub. No.: US 2008/0003739 A1
(43) Pub. Date: Jan. 3, 2008

(54) Method for forming isolation structure of flash memory device

(75) Inventors: Seung-Cheol Lee, Kyoungki-do (KR); Gyu-An Jin, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/647,744

(22) Filed: Dec. 28, 2006

(30) Foreign Application Priority Data
Jun. 29, 2006 (KR) 2006-0059855

(51) Int. Cl. H01L 21/8238; H01L 21/336

(52) U.S. Cl. 438/221; 438/424; 438/431; 438/257; 257/E21.546; 257/E21.549; 257/E21.573

(57) ABSTRACT

A method for forming an isolation structure of a flash memory device includes providing a substrate structure where a tunnel insulating layer, a conductive layer, and a padding layer are formed, etching the padding layer, the conductive layer, the tunnel insulating layer and the substrate to form a trench, forming a first insulating layer over the substrate structure and filling in a portion of the trench, forming a second insulating layer over the substrate structure, forming a third insulating layer over the substrate structure to fill the trench, polishing the first, second and third insulating layers using the padding layer as a polish stop layer, removing the padding layer and simultaneously recessing the third insulating layer to protrude the first and second insulating layers, and etching the first and second insulating layers while recessing the third insulating layer to form a protective layer on sidewalls of the conductive layer.

### CROSS-REFERENCE TO RELATED APPLICATIONS

The present invention claims priority of Korean patent application number 10-2006-0059855, filed on Jun. 29, 2006, which is incorporated by reference in its entirety.

### BACKGROUND OF THE INVENTION

The present invention relates to a semiconductor fabrication technology, and more particularly to a method for forming an isolation structure of a flash memory device.

With the development of fabrication technology of a semiconductor memory device, a line width of the semiconductor memory device is getting smaller and smaller. Accordingly, a width of a field region between active regions is also reduced. This causes an aspect ratio of a trench formed in the field region to be increased, and thus a filling process of an isolation structure into the trench becomes very difficult.

Therefore, to improve a filling property of the isolation structure, there has been proposed a technology of filling polysilazane (PSZ) into the trench instead of a typical high density plasma (HDP) undoped silicate glass (USG), wherein the PSZ is one kind of spin on dielectric (SOD) layers deposited using a spin coating method. However, the PSZ has a material property such as a high wet etch rate and a nonuniform etch, which makes an effective field oxide height (EFH) nonuniform in case of employing the wet etching process.

To solve the above-listed limitation of the PSZ, another technology has been introduced recently, in which a PSZ layer filling a trench is recessed to a given depth, and thereafter an HDP layer is deposited on the resultant structure. This technology is also applied to a self-aligned shallow trench isolation (SA-STI) process, which is one forming method of a floating gate in a flash memory device.

However, when performing the SA-STI process using the typical method for forming an isolation structure, a wafer should undergo chemical mechanical polishing (CMP) process twice for planarizing the PSZ layer and the HDP layer. That is, the CMP process should be performed after the deposition of the PSZ layer and the deposition of the HDP layer, respectively. This increases an EFH difference between the isolation structure formed in a central portion of the wafer and the isolation structure formed in an edge portion thereof. The EFH difference of the isolation structure according to positions of the wafer leads to a great variation of the EFH during a removal process of a pad nitride layer and an etching process for controlling the EFH of the isolation structure formed in a memory cell region. Thus, it may be difficult to control the EFH appropriately.

Meanwhile, as a space between active regions becomes smaller, a width of the isolation structure may be more reduced so that an interference margin between memory cells may become insufficient in a flash memory device of 60 nm or less. Since this insufficiency of the interference margin is generally one of the most important factors causing deteriorating characteristics of the flash memory device, it is often necessary to overcome the above limitation.

### SUMMARY OF THE INVENTION

Embodiments of the present invention are directed to provide a method for forming an isolation structure of a flash memory device, which can easily control an effective field oxide height (EFH) of the isolation structure formed in a memory cell region.

Other embodiments of the present invention are directed to provide a method for forming an isolation structure of a flash memory device, which can increase an interference margin between memory cells of the flash memory device.

In accordance with an aspect of the present invention, there is provided method for forming an isolation structure of a flash memory device, the method including: providing a substrate structure where a tunnel insulating layer, a conductive layer for a floating gate, and a padding layer are formed; etching the padding layer, the conductive layer, the tunnel insulating layer and a portion of the substrate to form a trench; forming a first insulating layer over the substrate structure and filling in a portion of the trench; forming a second insulating layer over the substrate structure; forming a third insulating layer over the substrate structure using a spin coating method to fill the trench; polishing the first, second and third insulating layers using the padding layer as a polish stop layer; removing the padding layer and simultaneously recessing the third insulating layer to protrude the first and second insulating layers; and etching the first and second insulating layers to a given thickness while recessing the third insulating layer to form a protective layer including the first and second insulating layers on sidewalls of the conductive layer.

### BRIEF DESCRIPTION OF THE DRAWINGS

FIGS. 1 to 8 illustrate cross-sectional views showing a method for forming an isolation structure of a flash memory device in accordance with an embodiment of the present invention.

### DESCRIPTION OF SPECIFIC EMBODIMENTS

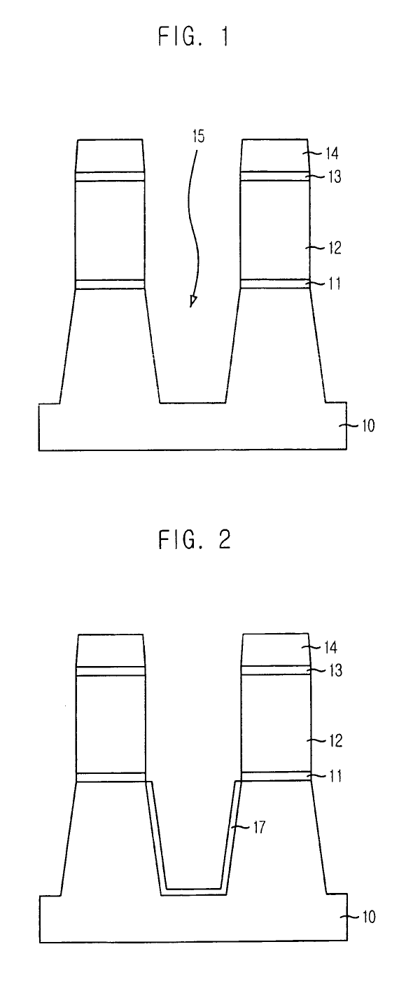

FIGS. 1 to 8 illustrate cross-sectional views showing a method for forming an isolation structure of a flash memory device in accordance with an embodiment of the present invention. For the sake of illustrative convenience, it will be illustrated a method for forming an isolation structure of a flash memory device in which a self-aligned shallow trench isolation (SA-STI) process is employed. In addition, it will be illustrated a portion of a memory cell region instead of an entire region of a wafer for the sake of conciseness.

Referring to FIG. 1, a tunnel insulating layer 11, a polysilicon layer 12 acting as a conductive layer for a floating gate, a buffer layer 13, and a padding layer 14 are formed over a substrate 10. The tunnel insulating layer 11 and the buffer layer 13 may include an oxide-based material, and the padding layer 14 may include a nitride-based material. Hereinafter, the tunnel insulating layer 11 is referred to as the tunnel oxide layer 11, the buffer layer 13 is referred to as the buffer oxide layer 13, and the padding layer 14 is referred to as the pad nitride layer 14. The pad nitride layer 14, the buffer oxide layer 13, the polysilicon layer 12, the tunnel oxide layer 11 and a portion of the substrate 10 are etched to a given depth, thereby forming a trench 15 in the substrate 10.

Referring to FIG. 2, an oxidation is performed to form an oxide layer 17 along an inside surface of the trench 15. Hereinafter, the oxide layer 17 is referred to as the wall oxide layer 17. For example, the wall oxide layer 17 may be formed to a thickness ranging from approximately 30 Å to approximately 80 Å at a process temperature ranging from approximately 700° C. to approximately 900° C. using furnace oxidation or radical oxidation process. The wall oxide layer 17 may be conformally formed to a thickness of approximately 30 Å.

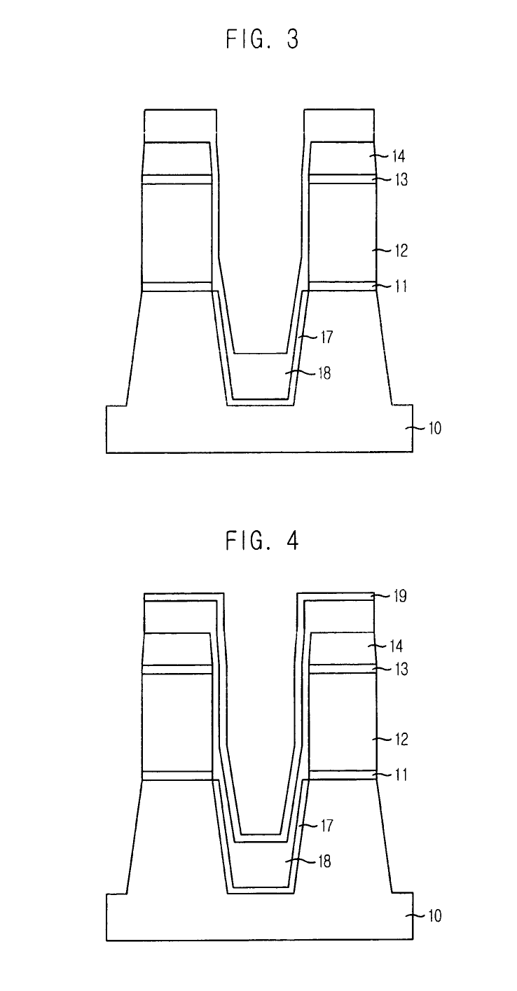

Referring to FIG. 3, a liner high density plasma (HDP) layer 18 is deposited on the resultant structure including the wall oxide layer 17 such that it fills the trench 15 partially. Herein, the liner HDP layer 18 acts as a protective layer for protecting both sidewalls of the polysilicon layer 12. The liner HDP layer 18 is formed to a total thickness ranging from approximately 1,000 Å to approximately 1,300 Å. Specifically, since the liner HDP layer 18 has a layer characteristic such that the deposition characteristic is better in a horizontal direction than a vertical direction, the liner HDP layer 18 is deposited to a thickness of approximately 100 Å on sidewalls of the trench 15 whereas it is deposited to a much greater thickness than approximately 100 Å on a bottom portion of the trench 15. For instance, the liner HDP layer 18 is formed to a thickness ranging from approximately 200 Å to approximately 1,000 Å over the bottom portion of the trench 15. Hydrogen concentration may be approximately 100 sccm in the liner HDP layer 18.

Referring to FIG. 4, a high temperature oxide (HTO) layer 19 is deposited on the resultant structure including the liner HDP layer 18 along a profile of the resultant structure. Here, the HTO layer 19 acts as another protective layer for protecting the sidewalls of the polysilicon layer 12. The HTO layer 19 is deposited to a thickness ranging from approximately 100 Å to approximately 150 Å using dichlorosilane (SiH₂Cl₂, DCS) as a source gas. The HTO layer 19 may be deposited to a thickness of approximately 150 Å. Accordingly, a final thickness of the liner HDP layer 18 and the HTO layer 19 formed on the sidewalls of the trench 15 is approximately 250 Å.

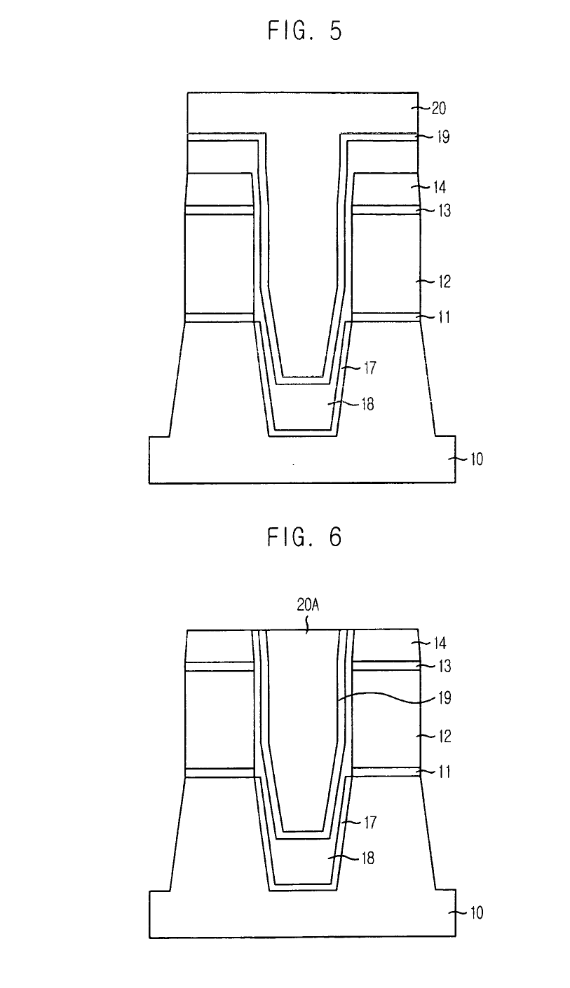

Referring to FIG. 5, a polysilizane (PSZ) layer 20 is formed on the HTO layer 19 such that the trench 15 is filled therewith. The PSZ layer 20 is one kind of spin on dielectric (SOD) layers formed by a spin coating method. Here, the PSZ layer 20 is formed to a thickness ranging from approximately 5,500 Å to approximately 6,000 Å.

A curing process is performed on the PSZ layer 20, and thereafter an annealing process is performed to densify the PSZ layer 20. The reason of performing the annealing process is to minimize a loss of the PSZ layer 20 by densifying the PSZ layer 20 during a following wet etching process. The annealing process may be performed for approximately 60 minutes at approximately 900° C. using nitrogen (N₂) gas, and the curing process may be performed for approximately 2 hours at approximately 350° C.

Referring to FIG. 6, the CMP process is performed to polish the PSZ layer 20 to form a polished PSZ layer 20A. The CMP process is performed using the pad nitride layer 14 as a polish stop layer. Specifically, a polish target is controlled such that a thickness of the pad nitride layer 14, which will be lost during the CMP process, should be in range of approximately 5 Å to approximately 15 Å. For example, in order to control a polishing selectivity between an oxide layer and a nitride layer, the CMP process is performed using low selectivity slurry (LSS) and high selectivity slurry (HSS) in sequence.

In particular, a cleaning process during the CMP process is performed using only ammonia. That is, a cleaning process using hydrogen fluoride (HF) is omitted herein. The reason is to maximally prevent the loss of the polished PSZ layer 20A caused by HF because the PSZ layer 20 has a high wet etch rate with respect to HF.

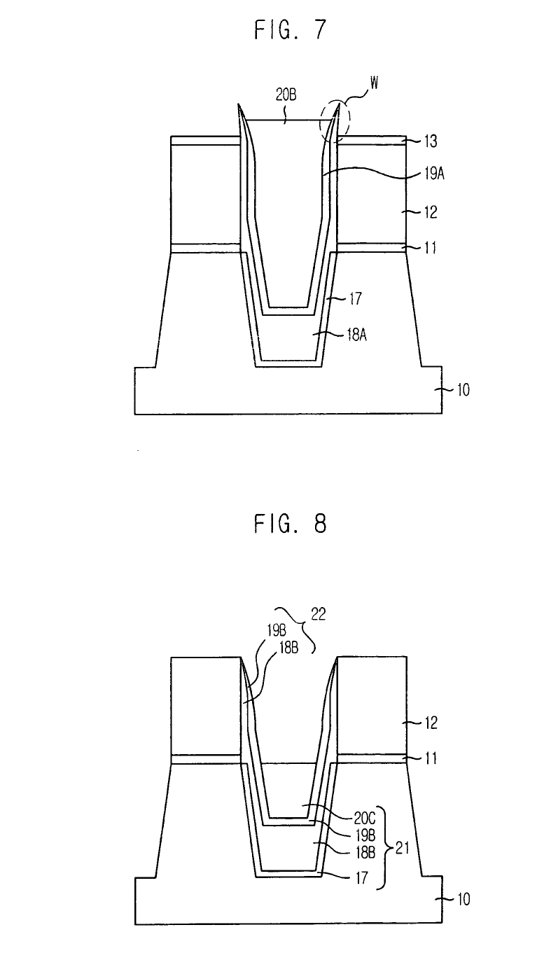

Referring to FIG. 7, a wet cleaning process is performed to remove the pad nitride layer 14. In the wet cleaning process, losses of the HTO layer 19 and the HDP layer 18 are minimized but the polished PSZ layer 20A is etched to a given depth together with the pad nitride layer 14, because there is an etch selectivity difference between the HTO layer 19 and the polished PSZ layer 20A. Reference denotations 20B, 19A, and 18A refer to an etched PSZ layer, an etched HTO layer, and an etched HDP layer, respectively. Therefore, a spacer wing W, which protrudes upward in the shape of a wing, is formed over the buffer oxide layer 13 so that the protective layer protrudes upward. Here, the height of the spacer wing W protruding from the top surface of the buffer oxide layer 13 is approximately 200 Å or less.

The polished PSZ layer 20A may be recessed to a given depth by using buffered oxide etchant (BOE) solution in which HF and ammonium fluoride (NH₄F) are mixed in a ratio of approximately 300:1 or HF solution diluted with H₂O in a ratio of approximately 100:1. Herein, the given etch depth of the polished PSZ layer 20A is smaller in a peripheral region than a memory cell region where memory cells are formed, because a pattern density of the peripheral region is lower than that of the memory cell region. For example, the etch depth of the polished PSZ layer 20A in the peripheral region is approximately a half of the etch depth of the polished PSZ layer 20A in the memory cell region. Although not shown, a peripheral region closed layer (PCL) mask is formed so as to selectively cover the peripheral region except semiconductor memory cells.

Referring to FIG. 8, a dry etching process is performed using the PLC mask such that the etched PSZ layer 20B is selectively etched in the cell region where the semiconductor memory cells are formed. Thus, the etched PSZ layer 20B of the cell region is selectively etched to a given depth, and simultaneously the spacer wing W and the buffer oxide layer 13 are removed to form a remaining PSZ layer 20C, a remaining HTO layer 19B, and a remaining HDP layer 18B. At this time, the spacer wing W of the peripheral region is still left remaining. Herein, the etched PSZ layer 20B can be appropriately etched to have a desired EFH by performing not wet etching process but dry etching process. Like above, the etching process using the PCL mask is performed for controlling the EFH of an isolation structure 21 formed in the cell region.

The PCL mask is removed through a stripping process, and a cleaning process is then performed. The cleaning process is performed for controlling the EFH of both the cell region and the peripheral region finally. Therefore, the isolation structure 21 having an optimized EFH is formed in the cell region, and a spacer 22 playing a role in protecting the sidewalls of the polysilicon layer 12 is formed on both sidewalls of the polysilicon layer 12. The spacer 22 may have a thickness of approximately 150 Å. In addition, the height of the top surface of the isolation structure 21 may be equal to or less than the top surface of the tunnel oxide layer 11. Accordingly, it is possible to secure the interference margin of the flash memory device by virtue of the formation of the spacer 22. Further, the device characteristic can be improved.

As described above, the present invention may provide several advantageous merits as follows. It may be possible to improve the device characteristic because a protective layer is naturally formed on the sidewalls of the conductive layer for the floating gate when employing the SA-STI process. Also, it may be possible to minimize the EFH variation according to the positions of the wafer by controlling the EFH of the isolation structure through the dry etching of the SOD layer which is the uppermost layer of the isolation structure, and by performing the CMP process only once. Therefore, the EFH of the isolation structure can be controlled with ease.

While the present invention has been described with respect to the specific embodiments, it will be apparent to those skilled in the art that various changes and modifications may be made without departing from the spirit and scope of the invention as defined in the following claims.

What is claimed is:

1. A method for forming an isolation structure of a flash memory device, the method comprising:
providing a substrate structure where a tunnel insulating layer, a conductive layer for a floating gate, and a padding layer are formed;
etching the padding layer, the conductive layer, the tunnel insulating layer and a portion of the substrate to form a trench;
forming a first insulating layer over the substrate structure and filling in a portion of the trench;
forming a second insulating layer over the substrate structure;
forming a third insulating layer over the substrate structure using a spin coating method to fill the trench;
polishing the first, second and third insulating layers using the padding layer as a polish stop layer;
removing the padding layer and simultaneously recessing the third insulating layer to protrude the first and second insulating layers; and
etching the first and second insulating layers to a given thickness while recessing the third insulating layer to form a protective layer including the first and second insulating layers on sidewalls of the conductive layer.

2. The method of claim 1, wherein the third insulating layer comprises a polysilazane (PSZ) layer.

3. The method of claim 1, wherein the first insulating layer comprises a high density plasma (HDP) layer.

4. The method of claim 1, wherein the second insulating layer comprises a high temperature oxide (HTO) layer.

5. The method of claim 1, further comprising, before the forming of the first insulating layer, forming an oxide layer on an inside surface of the trench.

6. The method of claim 5, wherein the oxide layer is formed to a thickness ranging from approximately 30 Å to approximately 80 Å at a process temperature ranging from approximately 700° C. to approximately 900° C. using furnace oxidation or radical oxidation process.

7. The method of claim 1, further comprising, after the forming of the conductive layer, forming a buffer layer between the conductive layer and the padding layer.

8. The method of claim 1, further comprising, before the polishing of the first, second and third insulating layers:
performing a curing process on the third insulating layer; and
performing an annealing process on the third insulating layer.

9. The method of claim 8, wherein performing the annealing process comprises using nitrogen (N₂) gas.

10. The method of claim 1, wherein the polishing of the first, second and third insulating layers comprises performing a cleaning process.

11. The method of claim 10, wherein performing the cleaning process comprises using ammonia gas.

12. The method of claim 9, wherein the forming of the protective layer comprises performing a dry etching process.

13. The method of claim 1, further comprising, after the forming of the protective layer, performing a cleaning process.

14. The method of claim 1, wherein the tunnel insulating layer comprises an oxide-based material.

15. The method of claim 1, wherein the padding layer comprises a nitride-based material.

16. The method of claim 7, wherein the buffer layer comprises an oxide-based material.
